(19) United States
(12) Patent Application Publication
(10) Pub. No.: US 2008/0217742 A1
(43) Pub. Date: Sep. 11, 2008

(54) TAILORED BIPOLAR TRANSISTOR DOPING PROFILE FOR IMPROVED RELIABILITY

(75) Inventors: Jeffrey B. Johnson, Essex Junction, VT (US); Edward J. Nowak, Essex Junction, VT (US); Andreas D. Stricker, Essex Junction, VT (US); Benjamin T. Voegeli, Burlington, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/684,142

(22) Filed: Mar. 9, 2007

(51) Int. Cl. H01L 29/732

(52) U.S. Cl. 257/592; 257/E29.185

(57) ABSTRACT

Bipolar transistor device structures that improve bipolar device reliability with little or no negative impact on device performance. In one embodiment, the bipolar device has a collector of first conductivity type material formed in a substrate, a base of a second conductivity type material including an extrinsic base layer and an intrinsic base layer, a raised emitter of a first conductivity type semiconductor material formed on the intrinsic base layer, and, a dielectric material layer separating the intrinsic base region and the raised emitter region, and, a thin “shunt” layer of dopant of second conductivity type material added to the region below the emitter dielectric layer. In a second embodiment, a selectively implanted collector (pedestal implant) is added to the vertical bipolar transistor device to enable a reduction in overall subcollector doping level to improve reliability without sacrificing device performance. These solutions add no additional masking steps and only one additional implantation step.

### FIELD OF THE INVENTION

The present invention related generally to the fabrication of semiconductor bipolar transistor devices, and more particularly, to a bipolar transistor device having a tailored transistor doping profile for improved reliability.

### BACKGROUND OF THE INVENTION

Bipolar transistor devices are designed with a trade-off between reliability and performance. In order to achieve high reliability, high speed performance of bipolar devices must sometimes be sacrificed. This is particularly true for high voltage applications.

In order to achieve high AC and DC performance, modern bipolar transistor devices generally include a raised emitter region. After the formation of the subcollector and base regions, the emitter structure formation begins with deposition of a layer of insulator material over the base region. An emitter window is then etched in the insulator material, followed by a deposition of a polycrystalline or single-crystalline -film, which is subsequently implanted and patterned to form a pedestal.

Specifically, high-performance vertical bipolar devices with polycrystalline emitter regions have dielectric layers which can trap charge, changing the device performance over time. In a vertical PNP device, having a collector base junction that is reverse-biased, for example, a high collector-base electric field results in some “hot” electrons which are injected upwards and can become trapped in the emitter-base dielectric. This is especially true if the dielectric layer includes silicon nitride, which has a high probability of trapping charge.

That is, when a high collector-base field is applied to the device while current is flowing in normal operation, some “hot” (charge) carriers are injected vertically upwards into the dielectric film underneath the emitter pedestal. The primary effect is in the extrinsic region of the device where the insulator exists. The collector-base field in the intrinsic region is of less importance to this reliability mechanism because no dielectric exists in this region. As charge builds in the dielectric region, an electric field is created which modifies the depletion of the emitter-base junction, causing a change in device performance over time. In some cases this can result in extreme, rapid changes (greater than 100% change in current gain after only a few seconds of operation has been observed).

One existing solution to this problem involves adjusting the collector-base doping profile in a manner that detracts from the high-speed performance of the transistor (e.g., widening the base or reducing collector doping). Another solution involves changing the dielectric film type and/or thickness, but this can have adverse affects on integration of other device types (e.g. disruption of FET performance in a BiCMOS process).

It would be highly desirable to provide a novel bipolar transistor device structure that exhibits increased reliability by tailoring the doping design of the formed bipolar transistor.

Moreover, it would be highly desirable to provide a novel bipolar transistor device structure that exhibits increased reliability by tailoring the doping design of the formed bipolar transistor in a manner that is compatible with current BiCMOS technologies.

### SUMMARY OF THE INVENTION

The present invention provides a novel semiconductor device structures designed to solve many performance-related problems for power-limited high-speed or low-power CMOS. Particularly, two embodiments of the invention are described that set forth device structures which improve bipolar device reliability, with little or no negative impact to device performance. These solutions add no additional masking steps and only one additional implantation step.

Thus, according to one aspect of the invention, a novel vertical bipolar transistor device comprises:
a semiconductor substrate;
a collector terminal of first conductivity type material formed in the substrate;
a base terminal of a second conductivity type semiconductor material including an extrinsic base layer and an intrinsic base layer;
a raised emitter region of a first conductivity type semiconductor material formed on the intrinsic base layer;
a layer of dielectric material separating a portion of the intrinsic base region and the raised emitter region; and
a doped layer of the second conductivity type material formed beneath the dielectric material layer of the raised emitter region, the doped layer of second conductivity type material shunting the effect of charge carriers from depleting the intrinsic base layer, thereby improving the reliability of the transistor.

According to a further aspect of the invention, there is provided a vertical bipolar transistor comprising:
a semiconductor substrate;
a subcollector terminal of first conductivity type material formed in the substrate;
a base terminal of a second conductivity type semiconductor material including an extrinsic base layer and an intrinsic base layer;
a raised emitter region of a first conductivity type semiconductor material formed on said intrinsic base layer;
a layer of dielectric material separating a portion of said intrinsic base region and said raised emitter region; and
a doped collector pedestal implant structure of first conductivity type material formed beneath said intrinsic base layer beneath said raised emitter region, said doped collector pedestal implant structure allowed for reduced overall subcollector doping level in order to improve transistor device reliability.

Advantageously, in each of the two embodiments of the invention, the reliability of both devices is enhanced with little or no sacrifice of AC and DC transistor device performance.

### BRIEF DESCRIPTION OF THE DRAWINGS

The objects, features and advantages of the present invention will become apparent to one skilled in the art, in view of the following detailed description taken in combination with the attached drawings, in which:

FIG. 1 depicts, through cross-sectional view, a vertical bipolar transistor device having a shunt layer for improved device reliability, according to a first embodiment of the invention;

FIG. 2 illustrates, through cross-sectional view, a processing step for forming the vertical bipolar transistor device having a shunt layer according to the first embodiment of the present invention;

FIG. 3 depicts, through a cross-sectional view, a vertical bipolar transistor device having a pedestal implant structure for improved device reliability, according to a second embodiment of the invention; and,

FIG. 4 depicts, through a cross-sectional view, a processing step for forming the vertical bipolar transistor device having a pedestal implant structure according to the second embodiment of the present invention.

### DETAILED DESCRIPTION OF THE PREFERRED EMBODIMENTS

The present invention is directed to a solution for improving bipolar transistor reliability with respect to hot carriers. In a first solution, a shallow base “shunt” implant is formed that comprises a layer of dopant material of the same species as the base which is placed immediately beneath the raised emitter region.

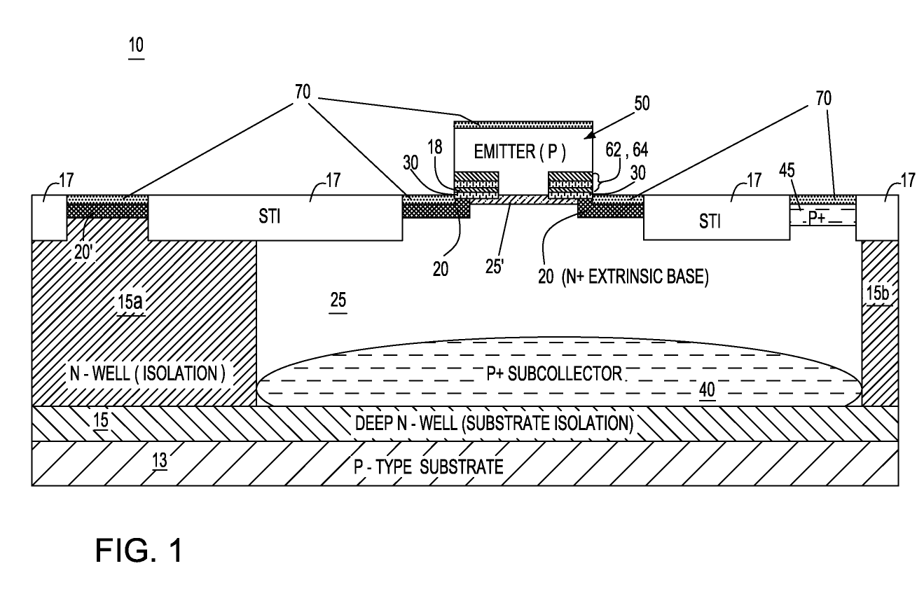

FIG. 1 shows, through cross-sectional view, an embodiment of a vertical bipolar transistor device 10 implementing a shallow base “shunt” implant according to a first embodiment of the invention. For purposes of discussion, the bipolar transistor device 10 is assumed to be a vertical PNP (VPNP) having a p-type emitter 50, an n-type intrinsic base 25 and a p-type collector 40. Filled STI (shallow trench oxide) regions 17 have been prior formed to isolate the transistor active device areas and contact regions as is conventionally known. In FIG. 1, there is formed in a p-type substrate 13, a deep N-Well implant 15 for isolation of the P-type collector 60 from the substrate and which can be shared with triple-well NFET in a BiCMOS process. The substrate 13 may comprise a bulk semiconductor substrate including, for example, Si, SiGe, SiC, SiGeC, GaAs, InP, InAs and other semiconductors, or layered semiconductors such as silicon-on-insulators (SOI), SiC-on-insulator (SiCOI) or silicon germanium-on-insulators (SGOI). The doping of the semiconductor substrate may vary for optimal device performance. Formed on top of the substrate by either growth or deposition techniques a thin dielectric layer 18, e.g., an oxide layer which is used as an implant screen, with a thickness in the range from about 2 nm to about 50 nm, and preferably in the range from about 5 nm to about 40 m. Additionally formed are implant N-Well regions 15a, 15b that provide lateral isolation of the P-type collector from substrate and which also can be shared with PFET N-Well in BiCMOS process. Using standard patterned lithography processes including deposition of a photoresist material, patterning and RIE etching, substrate surface regions are exposed that are subject to ion implantation for forming highly doped N⁺-type extrinsic base regions 20 and an N⁺-type base isolation contact region 20′ in the same implantation processing. It is understood That, in the formation of a BiCMOS, this implantation step may be shared with implantation for NFET source/drain and/or extensions (not shown). Having formed an extrinsic base, the device collector and base implant steps are performed to form the p-type subcollector 40 and n-type intrinsic base region 25. As shown in FIG. 1, as a result of the base implant steps, an n-type intrinsic base region 25′ is formed between the two highly doped N⁺-type extrinsic base regions 20.

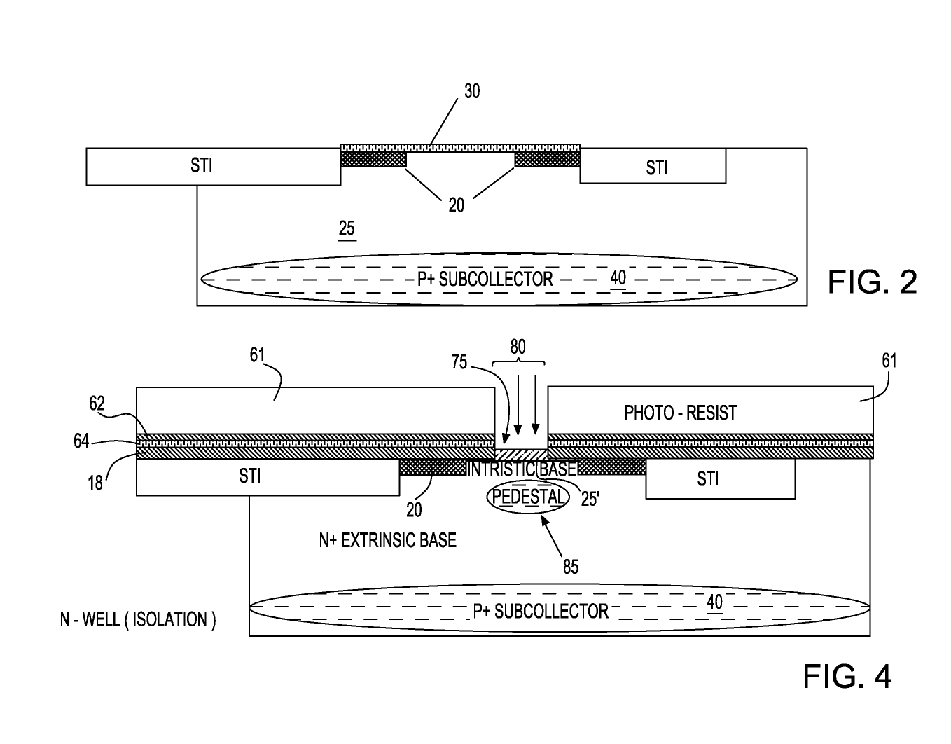

At this point in the process, after forming the p-type subcollector 40 and n-type intrinsic base regions 25, 25′, a very shallow n-type shunt implant layer 30 is formed as shown in FIG. 2. Particularly, the shunt layer 30 comprises a layer of dopant material of the same species as the base 25 which located immediately beneath the raised emitter region 50 to be formed. In fabrication of the shunt layer 30, dopant atoms are implanted at the substrate surface energies sufficient to pass through the thin dielectric layer 18, and at concentrations ranging from about 1.0×10¹⁸/cm ³ to about 1.0×10²¹/cm³, and preferably from about 1.0×10¹⁹/cm³ to about 1.0×10²⁰/cm³. The thickness of the shunt layer 30 is in the range from about 10 nm to about 100 nm, and preferably in the range from about 10 nm to about 50 nm.

Returning to FIG. 1, prior to forming the raised emitter structure, there is first grown or deposited emitter-base junction insulation layers 62, 64 of conventional thicknesses that may comprise an oxide or nitride material and formed over the prior-formed thin oxide layer 18. Preferably, the first pad layer 62 is a silicon oxide layer and the second pad layer 64 is a silicon nitride layer. The thickness of the first pad layer is in the range from about 10 nm to about 100 nm, and preferably in the range from about 20 nm to about 50 nm. The thickness of the second pad layer is in the range from about 10 nm to about 100 nm. Subsequently, the pad layers 62, 64 are thereafter lithographically patterned and removed from over the active semiconductor area of the formed intrinsic base portion 25′ of the device in the next emitter window mask/etch step. As a result of this patterned lithography, mask and etch steps, an emitter window is opened up that is aligned with and exposes a surface of the intrinsic base portion 25′. Then, an emitter material (e.g., Si and/or SiGe) is deposited which may comprise polycrystalline and/or monocrystalline silicon-containing material doped with dopant material of the same polarity and type as the dopants in the collector, e.g., p-type in a PNP transistor. For instance, the formed polysilicon emitter structure may comprise p-doped silicon, n-doped silicon, p-doped silicon germanium alloy, n-doped silicon germanium alloy, p-doped silicon carbon alloy, n-doped silicon carbon alloy, p-doped silicon germanium carbon alloy, n-doped silicon germanium carbon alloy, or any other semiconducting doped silicon alloy. As a PNP transistor is described for illustrative purposes, the emitter material may be in-situ doped p-type, or implanted with p-type material. Then, the raised emitter 50 is formed by performing an emitter pedestal mask/etch step and removing the pad layers 62, 64 to result in structure shown in FIG. 1. Finally, a P+-type collector contact 45 is formed by protecting the emitter and other device regions with a photoresist material and implanting P+-type material in an exposed collector contact region. This process step may be shared with PFET source/drain and/or extension processing when implementing BICMOS process. Subsequently, a thermal process such as an anneal or oxidation is performed in order to activate the dopants in the various regions of the device. In the preferred embodiment, this is performed via rapid thermal anneal (RTA) processing. This thermal processing also causes some dopant from the emitter material to out-diffuse downward in the region beneath the emitter window, forming the emitter-base junction in the underlying silicon. This out-diffusion sufficiently counter-dopes the thin shunt layer in the region beneath the emitter window.

Finally, metal silicide contact structures 70 may be formed at each of the isolation, base, emitter, and collector contact regions as shown in FIG. 1. These metal silicide contact structures 70 may comprises a CoSi (cobolt silicide) however, other metal materials may be used in the formation of the contact silicides that may include at least one of the following conductive elemental metals Ti, W, Ni, Cu, Pt, Ag, Au, Ru, Ir, Rh, and Re, and/or alloys that include at least one of the aforementioned conductive elemental metals.

Thus, in the first embodiment of the invention, an implant step (FIG. 2) is performed just prior to the deposition of the insulator films 62, 64. A dopant of the same species as the base dopant is implanted at low energy, forming a highly doped “shunt” in the extrinsic region 20 of the device. This dopant layer is counter-doped by downward diffusion of the emitter dopant from the emitter material in the region of the device beneath the emitter window, thus minimizing the effect of the shunt on the vertical doping profile in this region. The shunt layer is designed to be sufficiently thin such that the out-diffusion of the emitter dopant is deep enough to completely counter-dope the shunt layer. In this solution, the electric field which results from trapped charge in the dielectric has less of an effect on the depletion of the emitter-base junction, since the region of the base below the emitter dielectric is more highly doped. This has been demonstrated empirically to improve reliability by a factor of 10 for vertical PNP transistor BiCMOS technology, with only a small impact on the device performance.

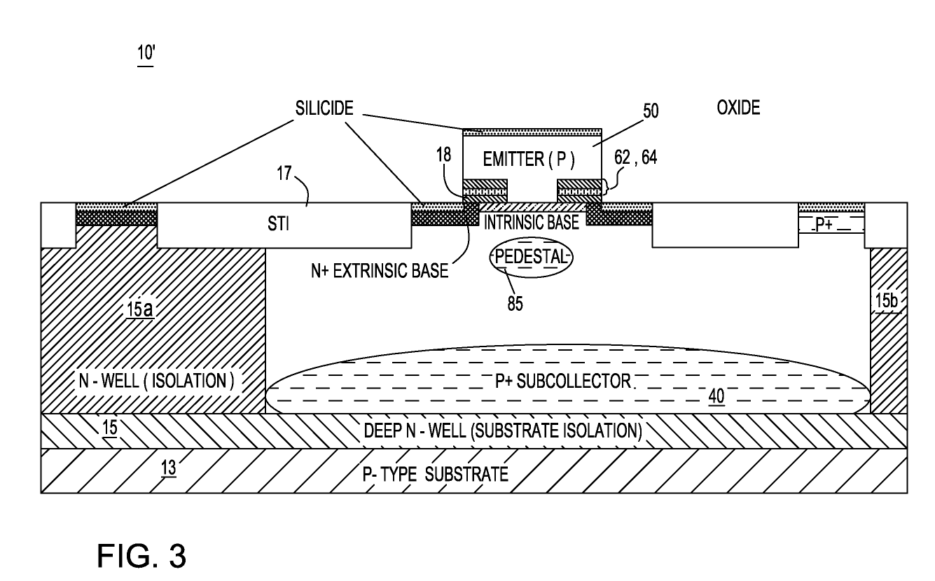

FIG. 3 shows, through cross-sectional view, an embodiment of a vertical bipolar transistor device 10′ according to a second embodiment of the invention. In this second embodiment, an implant step (FIG. 4) is performed just after the emitter window etch step, using a dopant of the same species as the collector dopant. That is, as shown in FIG. 4, after deposition of the emitter-base insulation layers 62, 64, formed over thin oxide layer 18, a photolithographic patterning step is performed to open up a window and expose the surface 75 of the intrinsic base 20. This step includes: application of a photoresist layer 61 and RIE or like etching to remove all three dielectric layers 18, 62 and 64 to expose the intrinsic base active device surface. In the exposed window, a dopant material is implanted using a dopant of the same polarity as the collector dopant (e.g., p-type for the example embodiment described) at concentration and energies sufficient to form the selectively implanted collector (SIC) or pedestal region 85 below the intrinsic base. This pedestal may be doped to a concentration ranging anywhere from 1e¹⁶ cm⁻³ to 1e¹⁸ cm⁻³. The energy of the pedestal implant is adjusted such that the pedestal region resides approximately in the range of 50 nm to 250 nm below the intrinsic base region, preferably 100 nm to 200 nm below the intrinsic base region. The thickness of the pedestal region will depend on the implant energy due to longitudinal implant straggle, and will range from 50 nm to 500 nm, preferably in the range of 100 nm to 300 nm. The processing then continues with emitter film deposition, as described herein with respect to FIG. 1.

It is understood that, this added implant enhances the doping profile of the collector only in the region under the emitter opening (the intrinsic device), thus increasing the high-speed performance of the device with minimal impact to reliability. As a result, the subcollector doping level can be reduced while still achieving high alternating current (AC) and direct current (DC) performance, which is largely driven by the doping profile in the intrinsic region. Reducing the doping concentration in the subcollector reduces the electric field in the extrinsic collector-base junction, thus reducing the number of hot carriers which are injected vertically into the dielectric region. This technique can improve the reliability of a vertical PNP device by a factor of 1000 in BiCMOS technology, while maintaining equivalent AC performance and improving the DC performance.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

Having thus described our invention, what we claim as new, and desire to secure by Letters Patent is:

1. A vertical bipolar transistor comprising:
a semiconductor substrate;
a collector terminal of first conductivity type material formed in said substrate;
a base terminal of a second conductivity type semiconductor material including an extrinsic base layer and an intrinsic base layer;
a raised emitter region of a first conductivity type semiconductor material formed on said intrinsic base layer;
a layer of dielectric material separating a portion of said intrinsic base region and said raised emitter region; and
a doped layer of said second conductivity type material formed beneath said dielectric material layer of raised emitter region, said doped layer of second conductivity type material shunting the effect of charge carriers from depleting the intrinsic base layer, thereby improving the reliability of the transistor.

2. The vertical bipolar transistor as claimed in claim 1, wherein said dielectric layer includes a nitride material that traps charge carriers in the emitter and depletes the intrinsic base layer, said doped layer of second conductivity type material being sufficiently doped to reduce the depletion of the intrinsic base layer.

3. The vertical bipolar transistor as claimed in claim 2, wherein a dopant concentration of said doped layer of second conductivity type material ranges between 1.0×10¹⁸/cm³ and 1.0×10²¹/cm³.

4. The vertical bipolar transistor as claimed in claim 2, wherein a thickness of said doped layer of second conductivity type material ranges between 10 nm and 100 nm.

5. The vertical bipolar transistor as claimed in claim 2, wherein said doped layer of second conductivity type material provides charge carriers such that a charging effect of the nitride layer is buffered from the intrinsic base layer, thereby reducing the depletion of an emitter-base junction.

6. The vertical bipolar transistor as claimed in claim 2, wherein said device is a p-n-p bipolar transistor device, the doped layer of second conductivity type material providing n-type carriers.

7. A vertical bipolar transistor comprising:
a semiconductor substrate;
a subcollector terminal of first conductivity type material formed in said substrate;
a base terminal of a second conductivity type semiconductor material including an extrinsic base layer and an intrinsic base layer;
a raised emitter region of a first conductivity type semiconductor material formed on said intrinsic base layer;
a layer of dielectric material separating a portion of said intrinsic base region and said raised emitter region; and
a doped collector pedestal implant structure of first conductivity type material formed beneath said intrinsic base layer beneath said raised emitter region, said doped collector pedestal implant structure allowed for reduced overall subcollector doping level in order to improve transistor device reliability.

8. The vertical bipolar transistor as claimed in claim 7, wherein said doped subcollector region doping level is reduced in order to reduce an electric field in an extrinsic collector-base junction, thus reducing a number of charge carriers that are injected into the dielectric region.

9. The vertical bipolar transistor as claimed in claim 8, wherein said doped collector pedestal increases the doping level in the collector region immediately beneath the emitter, thereby enabling reduction in overall subcollector doping level to improve transistor reliability without sacrificing device performance.

10. The vertical bipolar transistor as claimed in claim 8, wherein a dopant concentration of said doped collector pedestal ranges between 1.0×10¹⁶/cm³ and 1.0×10^{˜}/cm³.

11. The vertical bipolar transistor as claimed in claim 8, wherein a thickness of said doped collector pedestal ranges between 50 nm and 500 nm.
